(19) United States
(12) Patent Application Publication
(10) Pub. No.: US 2023/0333610 A1
(43) Pub. Date: Oct. 19, 2023

(54) SECURE HARDWARE COMPONENT RETENTION ASSEMBLY

(71) Applicant: Dell Products L.P., Round Rock, TX (US)

(72) Inventors: Anthony Wayne Howard, Austin, TX (US); Ray Vivian Kacelenga, Cedar Park, TX (US); Isaac Qin Wang, Austin, TX (US)

(21) Appl. No.: 17/659,020

(22) Filed: Apr. 13, 2022

(51) Int. Cl. G06F 1/18; H05K 7/14

(52) U.S. Cl. CPC G06F 1/186; H05K 7/1487

(57) ABSTRACT

A secure hardware component retention assembly, including a tray assembly moveably coupled to an information handling system (IHS), the tray assembly including a coupling member and a spring element; a hardware component coupled to the tray assembly; a fastening element coupled to the IHS; wherein when the fastening element is in a first state, the fastening element is engaged with the coupling member to maintain a first positioning of the tray assembly internal to the IHS and the hardware component is engaged with a connector of the IHS, wherein when the fastening element is in a second state, the fastening element is disengaged from the coupling member such that the spring element exerts a force to translate the tray assembly so as to i) position at least a portion of the tray assembly external to the IHS and ii) disengage the hardware component from the connector of the HIS.

### BACKGROUND

### Field of the Disclosure

The disclosure relates generally to an information handling system, and in particular, a secure hardware component retention assembly for the information handling system.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

### SUMMARY

Innovative aspects of the subject matter described in this specification may be embodied in a secure hardware component retention assembly, including a tray assembly moveably coupled to an information handling system, the tray assembly including a coupling member and a spring element; a hardware component coupled to the tray assembly; and a fastening element coupled to the information handling system; wherein when the fastening element is in a first state, the fastening element is engaged with the coupling member to maintain a first positioning of the tray assembly internal to the information handling system and the hardware component is engaged with a connector of the information handling system, wherein when the fastening element is in a second state, the fastening element is disengaged from the coupling member such that the spring element exerts a force to translate the tray assembly so as to i) position at least a portion of the tray assembly external to the information handling system and ii) disengage the hardware component from the connector of the information handling system, wherein the fastening element transitions from the first state to the second state in response to a signal.

Other embodiments of these aspects include corresponding systems and apparatus.

These and other embodiments may each optionally include one or more of the following features. For instance, further comprising an extension spring coupled to the fastening element, the extension spring exerting a first force on the fastening element to maintain the fastening element in the first state. Further comprising a shape memory alloy element coupled to the fastening element, wherein in response to the signal, the shape memory alloy element contracts to exert a second force on the fastening element to overcome the first force of the extension spring and place the fastening element in the second state. The fastening element includes a hooking member and the coupling member includes a post, wherein the extension spring exerts the first force on the fastening element such that the hooking member engages the post to maintain the fastening element in the first state. The shape memory alloy element contracts, in response to the signal, to exert the second force on the fastening element such that the hooking member disengages from the post to place the fastening element in the second state. When the fastening element is in the first state, the spring element is in a compressed state. The fastening element is rotatably coupled to the information handling system. The fastening element is a solenoid and the coupling member is an opening, wherein when the solenoid is in the first state, a latch pin of the solenoid engages with the opening to maintain the first positioning of the tray assembly. Further comprising a shape memory alloy element coupled to the solenoid, wherein the shape memory alloy element contracts, in response to the signal, to disengage the latch pin of the solenoid from the opening to place the solenoid in the second state. The hardware component is a solid-state drive. The hardware component is a memory module. The hardware component is a subscriber identification module. The connector is a M.2 connector.

Particular implementations of the subject matter described in this specification can be implemented so as to realize one or more of the following advantages. For example, externally accessible hardware components are secured against bad actors attempting to remove the hardware components to maintain data privacy; and the hardware components can be removed via a secured tool-less mechanism.

The details of one or more embodiments of the subject matter described in this specification are set forth in the accompanying drawings and the description below. Other potential features, aspects, and advantages of the subject matter will become apparent from the description, the drawings, and the claims.

### BRIEF DESCRIPTION OF DRAWINGS

FIG. 1 is a block diagram of selected elements of an embodiment of an information handling system.

FIG. 2 illustrates a block diagram of an information handling system for including a secure hardware component retention assembly.

FIGS. 3A-3C illustrate the information handling system and the secure hardware component retention assembly.

FIGS. 4A-4C illustrate the secure hardware component retention assembly, in various states, in a first embodiment.

FIGS. 5A-5C illustrate the secure hardware component retention assembly, in various states, in a second embodiment.

FIG. 6 illustrates a block diagram of an information handling system for including a secure hardware component retention assembly.

FIGS. 7A-7C illustrate the secure hardware component retention assembly, in various states, in a third embodiment.

FIG. 8 illustrates a method for utilizing the secure hardware component retention assembly.

### DESCRIPTION OF PARTICULAR EMBODIMENT(S)

This disclosure discusses a secure hardware component retention assembly of an information handling system. In short, a secure hardware component retention assembly can secure hardware components within the information handling system. The hardware components can be removed after user-authentication, and powering down the hardware component.

Specifically, this disclosure discusses a tray assembly moveably coupled to an information handling system, the tray assembly including a coupling member and a spring element; a hardware component coupled to the tray assembly; and a fastening element coupled to the information handling system; wherein when the fastening element is in a first state, the fastening element is engaged with the coupling member to maintain a first positioning of the tray assembly internal to the information handling system and the hardware component is engaged with a connector of the information handling system, wherein when the fastening element is in a second state, the fastening element is disengaged from the coupling member such that the spring element exerts a force to translate the tray assembly so as to i) position at least a portion of the tray assembly external to the information handling system and ii) disengage the hardware component from the connector of the information handling system, wherein the fastening element transitions from the first state to the second state in response to a signal.

Further, this disclosure discusses a secure hardware component retention assembly, including an access door including a coupling member; a torsional spring hinge coupling the access door to an information handling system; a hardware component engaged with a connector of the information handling system; and a fastening element coupled to the information handling system, wherein when the fastening element is in a first state, the fastening element is engaged with the coupling member to maintain a first positioning of the access door so as to conceal the hardware component within a casing of the information handling system, wherein when the fastening element is in a second state, the fastening element is disengaged from the coupling member such that the torsional spring hinge rotates the access door so as to expose the hardware component, wherein the fastening element transitions from the first state to the second state in response to a signal.

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such wires, optical fibers, microwaves, radio waves, and other electromagnetic and/or optical carriers; and/or any combination of the foregoing.

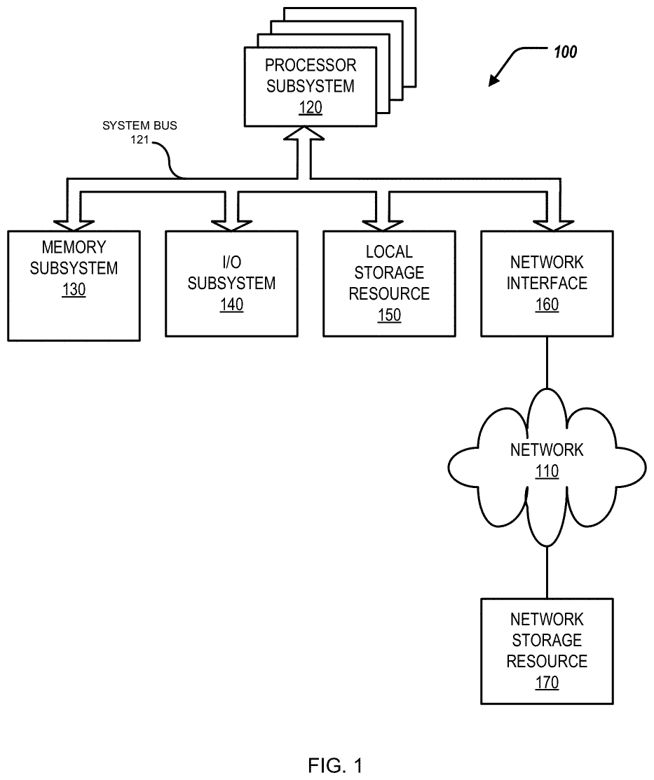

Particular embodiments are best understood by reference to FIGS. 1-8 wherein like numbers are used to indicate like and corresponding parts.

Turning now to the drawings, FIG. 1 illustrates a block diagram depicting selected elements of an information handling system 100 in accordance with some embodiments of the present disclosure. In various embodiments, information handling system 100 may represent different types of portable information handling systems, such as, display devices, head mounted displays, head mount display systems, smart phones, tablet computers, notebook computers, media players, digital cameras, 2-in-1 tablet-laptop combination computers, and wireless organizers, or other types of portable information handling systems. In one or more embodiments, information handling system 100 may also represent other types of information handling systems, including desktop computers, server systems, controllers, and microcontroller units, among other types of information handling systems. Components of information handling system 100 may include, but are not limited to, a processor subsystem 120, which may comprise one or more processors, and system bus 121 that communicatively couples various system components to processor subsystem 120 including, for example, a memory subsystem 130, an I/O subsystem 140, a local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

As depicted in FIG. 1, processor subsystem 120 may comprise a system, device, or apparatus operable to interpret and/or execute program instructions and/or process data, and may include a microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of information handling system). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

In information handling system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. In various embodiments, I/O subsystem 140 may be used to support various peripheral devices, such as a touch panel, a display adapter, a keyboard, an accelerometer, a touch pad, a gyroscope, an IR sensor, a microphone, a sensor, a camera, or another type of peripheral device.

Local storage resource 150 may comprise computer-readable media (e.g., hard disk drive, floppy disk drive, CD-ROM, and/or other type of rotating storage media, flash memory, EEPROM, and/or another type of solid state storage media) and may be generally operable to store instructions and/or data. Likewise, the network storage resource 170 may comprise computer-readable media (e.g., hard disk drive, floppy disk drive, CD-ROM, and/or other type of rotating storage media, flash memory, EEPROM, and/or other type of solid state storage media) and may be generally operable to store instructions and/or data.

In FIG. 1, network interface 160 may be a suitable system, apparatus, or device operable to serve as an interface between information handling system 100 and a network 110. Network interface 160 may enable information handling system 100 to communicate over network 110 using a suitable transmission protocol and/or standard, including, but not limited to, transmission protocols and/or standards enumerated below with respect to the discussion of network 110. In some embodiments, network interface 160 may be communicatively coupled via network 110 to a network storage resource 170. Network 110 may be a public network or a private (e.g. corporate) network. The network may be implemented as, or may be a part of, a storage area network (SAN), personal area network (PAN), local area network (LAN), a metropolitan area network (MAN), a wide area network (WAN), a wireless local area network (WLAN), a wireless wide area network (WWAN), a virtual private network (VPN), an intranet, the Internet or another appropriate architecture or system that facilitates the communication of signals, data and/or messages (generally referred to as data). Network interface 160 may enable wired and/or wireless communications (e.g., NFC or Bluetooth) to and/or from information handling system 100.

In particular embodiments, network 110 may include one or more routers for routing data between client information handling systems 100 and server information handling systems 100. A device (e.g., a client information handling system 100 or a server information handling system 100) on network 110 may be addressed by a corresponding network address including, for example, an Internet protocol (IP) address, an Internet name, a Windows Internet name service (WINS) name, a domain name or other system name. In particular embodiments, network 110 may include one or more logical groupings of network devices such as, for example, one or more sites (e.g. customer sites) or subnets. As an example, a corporate network may include potentially thousands of offices or branches, each with its own subnet (or multiple subnets) having many devices. One or more client information handling systems 100 may communicate with one or more server information handling systems 100 via any suitable connection including, for example, a modem connection, a LAN connection including the Ethernet or a broadband WAN connection including DSL, Cable, Ti, T3, Fiber Optics, Wi-Fi, or a mobile network connection including GSM, GPRS, 3G, or WiMax.

Network 110 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 110 and its various components may be implemented using hardware, software, or any combination thereof.

In short, a secure hardware component retention assembly can secure hardware components within the information handling system 100. The hardware components can be removed after user-authentication, and after powering down of the hardware component(s).

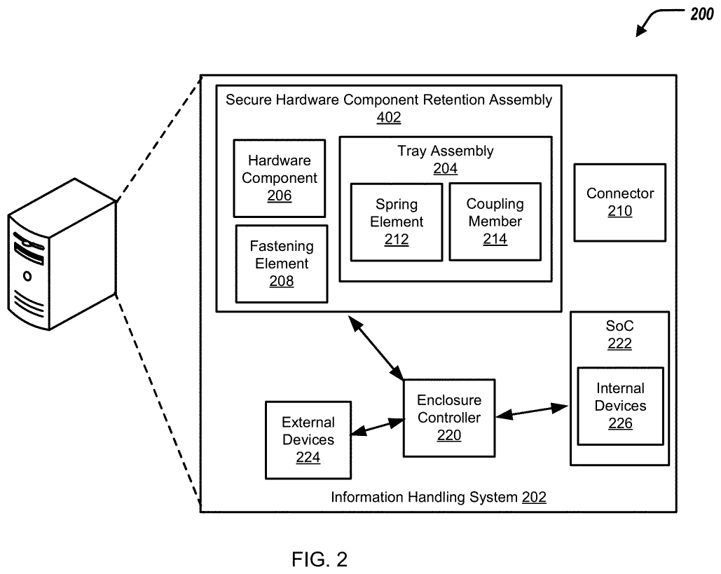

Turning to FIG. 2, FIG. 2 illustrates an environment 200 including an information handling system 202. The information handling system 202 can include a secure hardware component retention assembly 402 and a connector 210. The assembly 402 can include tray assembly 204, a hardware component 206, and a fastening element 208. In some examples, the information handling system 202 is similar to, or includes, the information handling system 100 of FIG. 1. The tray assembly 204 can include a spring element 212 and a coupling member 214.

The information handling system 202 can further include an enclosure controller 220, a system on a chip (SoC) 222, and external devices 224. The SoC 222 can further include internal devices 226. The enclosure controller (EC) 220 can be in communication with the assembly 402, the external devices 224, and the SoC 222.

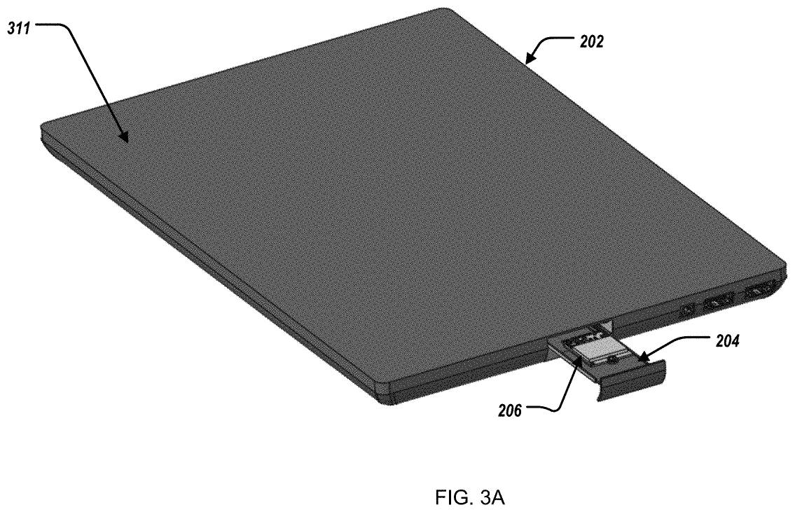

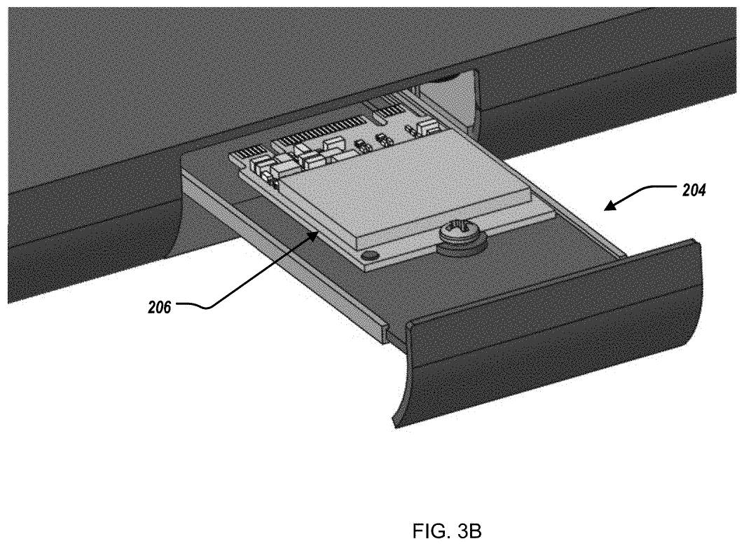

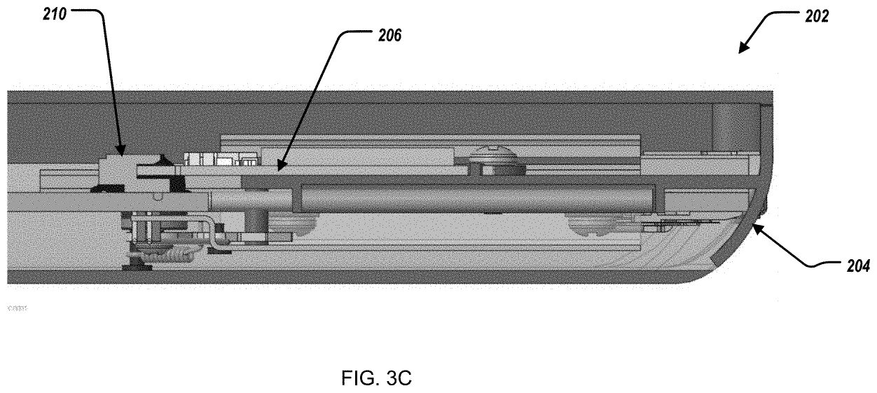

FIG. 3A illustrates a perspective view of the information handling system 202, and in particular, the tray assembly 204. As illustrated, the tray assembly 204 is moveably coupled to the information handling system 202. That is, the tray assembly 204 can be coupled to the information handling system 202, and further, moveably (or slidably) with respect to the information handling system 202. FIG. 3B illustrates a close-up perspective view of the tray assembly 204, and in particular, the hardware component 206 coupled to the tray assembly 204. FIG. 3C illustrates a side cut-away view of the information handling system 202. The hardware component 206 can be coupled to the connector 210.

In some examples, the hardware component 206 is a solid-state drive (SSD). In some examples, the hardware component 206 is a memory module (MINIM). In some examples, the hardware component 206 is a subscriber identification module (SIM).

In some examples, the connector 210 is a M.2 connector. In some examples, the connector 210 is a DIMM connector. In some examples, the connector 210 is a SIM connector.

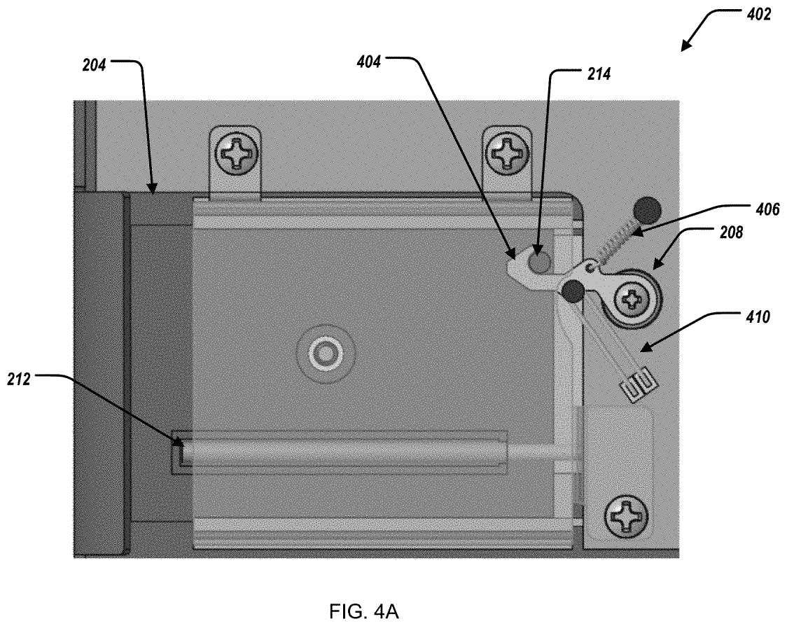

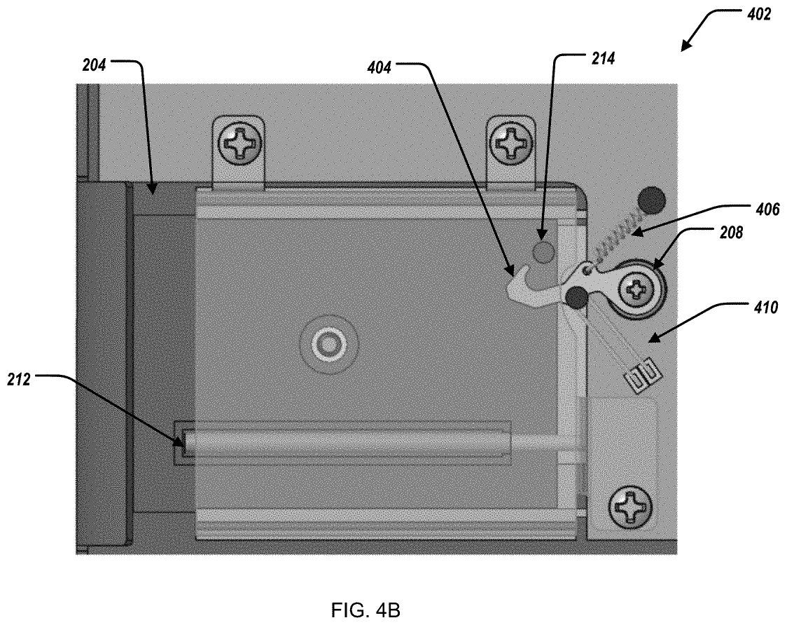

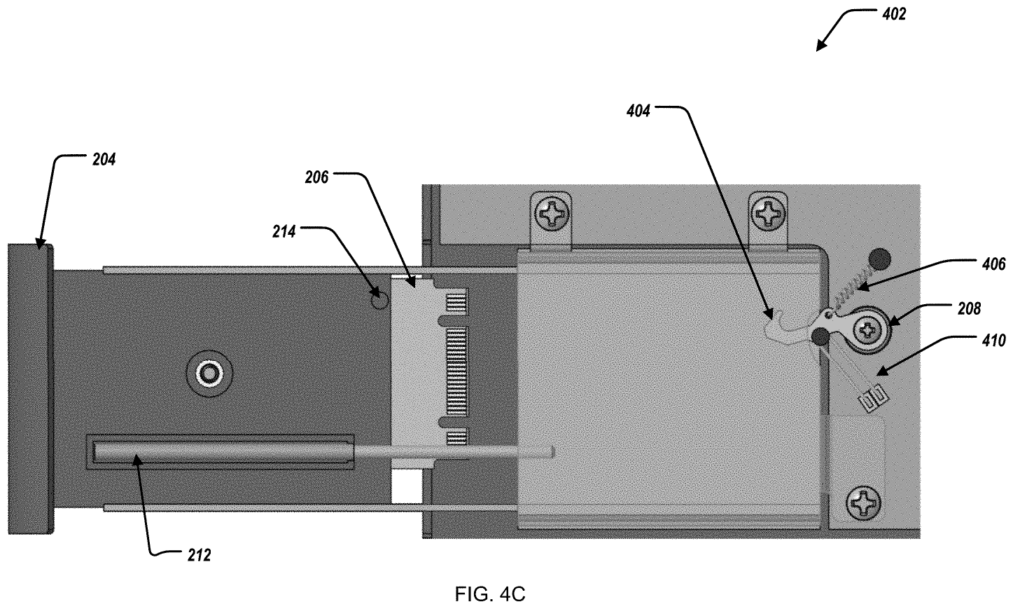

FIGS. 4A-4C illustrate a top down view of the secure hardware component retention assembly 402, in a first implementation. The tray assembly 204 can include the spring element 212 and the coupling member 214. The assembly 402 can further include the fastening element 208 coupled to the information handling system 202. In some examples, the fastening element 208 includes a hooking member 404. In some examples, the fastening element 208 is rotatably coupled to the information handling system 202. The assembly 402 can further include an extension spring 406 coupled to the fastening element 208. In some examples, the coupling member 214 includes a post.

The assembly 402 can further include a shape memory alloy element 410 (muscle wire 410) coupled to the fastening element 208.

FIG. 4A illustrates the fastening element 208 in a first state. Specifically, when the fastening element 208 is in the first state, the fastening element 208 is engaged with the coupling member 214 to maintain a first positioning of the tray assembly 204 internal to the information handling system 202, and further, the hardware component 206 (shown in FIGS. 3A-3C) is engaged with the connector 210 (shown in FIGS. 3A-3C) of the information handling system 202. Specifically, the extension spring 406 exerts a first force on the fastening element 208 to maintain the fastening element 208 in the first state, and in particular, the hooking member 404 of the fastening element 208 engages the coupling member 214 (the post) to maintain the fastening element 208 in the first state. Moreover, when the fastening element 208 is in the first state, the spring element 212 is in a compressed state.

The shape memory alloy element 410 can receive a signal indicating to transition the fastening element 208 from the first state to a second state, as shown in FIG. 4B. Specifically, the shape memory alloy element 410, in response to the signal, contracts to exert a second force on the fastening element 208 to overcome the first force of the extension spring 406 and place the fastening element 208 in the second state. That is, when the fastening element 208 is in the second state, the fastening element 208 is disengaged from the coupling member 214, and in particular, the hooking member 404 of the fastening element 208 is disengaged from the coupling member 214 (post).

Furthermore, when the fastening element 208 is disengaged from the coupling member 214, the spring element 212 is able to exert a force to translate the tray assembly 204 (release stored spring force on a fixture of the information handling system 202). As a result, at least a portion of the tray assembly 204 is positioned external to the information handling system 202, as shown in FIG. 4C. Furthermore, the hardware component 206 is disengaged from the connector 210 (shown in FIGS. 3A-3C) of the information handling system 202.

In short, the fastening element 208 transitions from the first state to the second state in response to the signal.

In some cases, a user of the information handling system 202 provides input that generates the signal to transition the fastening element 208 from the first state to the second state, and provide access to the hardware component 206. The user can be authenticated (e.g., via login credentials or biometric means).

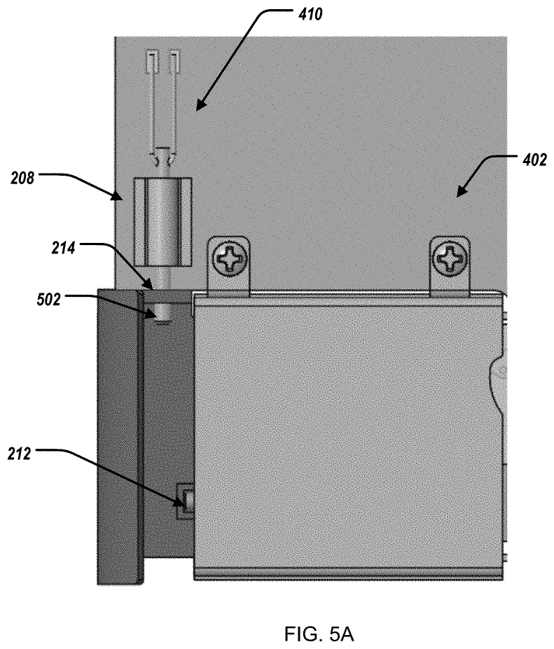

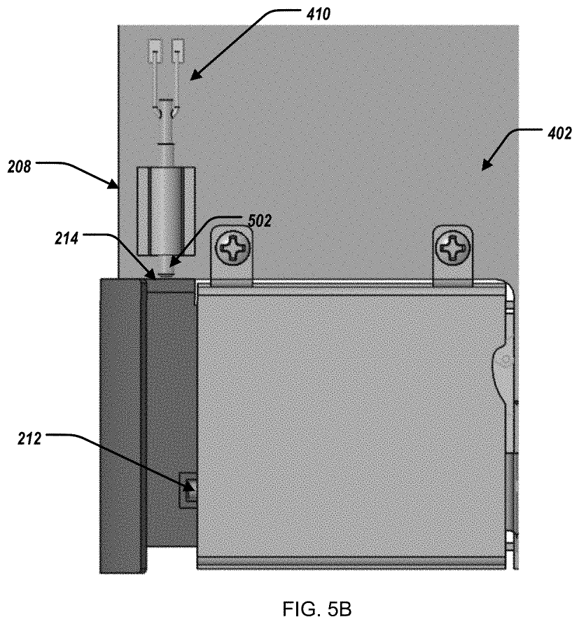

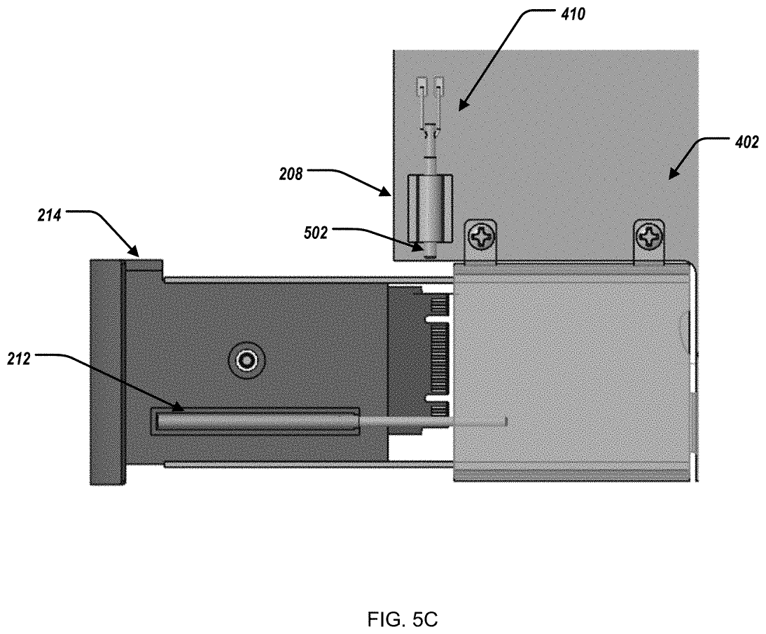

FIGS. 5A-5C illustrate a top down view of a secure hardware component retention assembly 402, in a second implementation. The tray assembly 204 can include the spring element 212 and the coupling member 214. In some examples, the coupling member 214 is an opening. The assembly 402 can further include the fastening element 208 coupled to the information handling system 202. In some examples, the fastening element 208 is a solenoid, and includes a latch pin 502.

The assembly 402 can further include the shape memory alloy element 410 (muscle wire 410) coupled to the fastening element 208 (solenoid).

FIG. 5A illustrates the fastening element 208 (solenoid) in a first state. Specifically, when the fastening element 208 is in the first state, the latch pin 502 of the fastening element 208 (solenoid) is engaged with the coupling member 214 (opening) to maintain a first positioning of the tray assembly 204 internal to the information handling system 202, and further, the hardware component 206 (shown in FIGS. 3A-3C) is engaged with the connector 210 (shown in FIGS. 3A-3C) of the information handling system 202. Moreover, when the fastening element 208 is in the first state, the spring element 212 is in a compressed state.

The shape memory alloy element 410 can receive a signal indicating to transition the fastening element 208 (solenoid) from the first state to a second state, as shown in FIG. 5B. Specifically, the shape memory alloy element 410, in response to the signal, contracts to disengage the latch pin 502 of the fastening element 208 (solenoid) from the coupling member 214 (opening) to place the fastening element 208 (solenoid) in the second state.

Furthermore, when the fastening element 208 (solenoid) is disengaged from the coupling member 214 (opening), the spring element 212 is able to exert a force to translate the tray assembly 204 (release stored spring force on a fixture of the information handling system 202). As a result, at least a portion of the tray assembly 204 is positioned external to the information handling system 202, as shown in FIG. 5C. Furthermore, the hardware component 206 is disengaged from the connector 210 (shown in FIGS. 3A-3C) of the information handling system 202.

In short, the fastening element 208 (solenoid) transitions from the first state to the second state in response to the signal.

In some cases, a user of the information handling system 202 provides input that generates the signal to transition the fastening element 208 from the first state to the second state, and provide access to the hardware component 206. The user can be authenticated (e.g., via login credentials or biometric means).

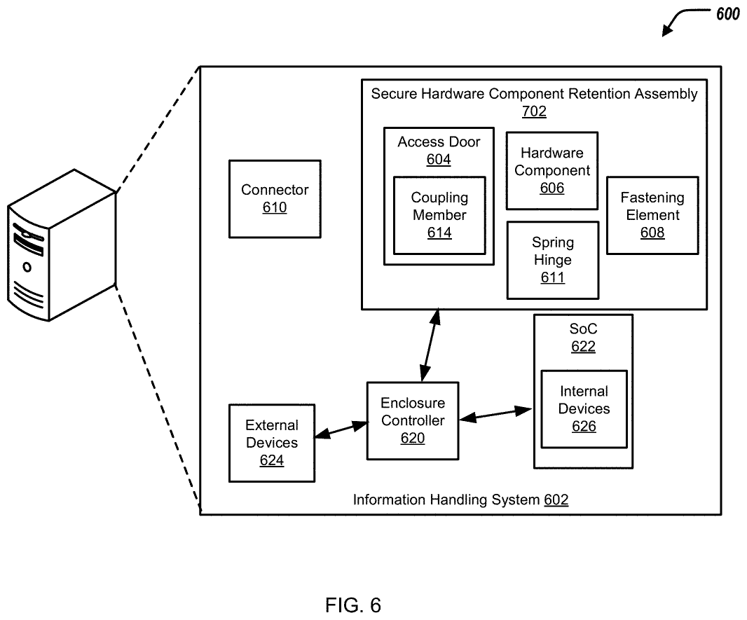

Turning to FIG. 6, FIG. 6 illustrates an environment 600 including an information handling system 602. The information handling system 602 can include a secure hardware component retention assembly 702 and a connector 610. The assembly 702 can include an access door 604, a hardware component 606, a fastening element 608, and a (torsional) spring hinge 611. In some examples, the information handling system 602 is similar to, or includes, the information handling system 100 of FIG. 1. The access door 604 can include a coupling member 614.

The information handling system 602 can further include an enclosure controller 620, a system on a chip (SoC) 622, and external devices 624. The SoC 622 can further include internal devices 626. The enclosure controller (EC) 620 can be in communication with the assembly 702, the external devices 624, and the SoC 622.

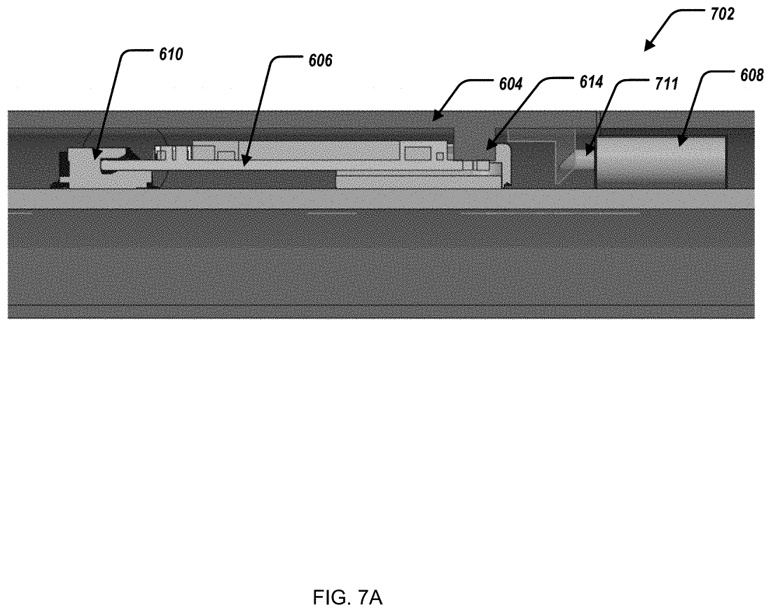

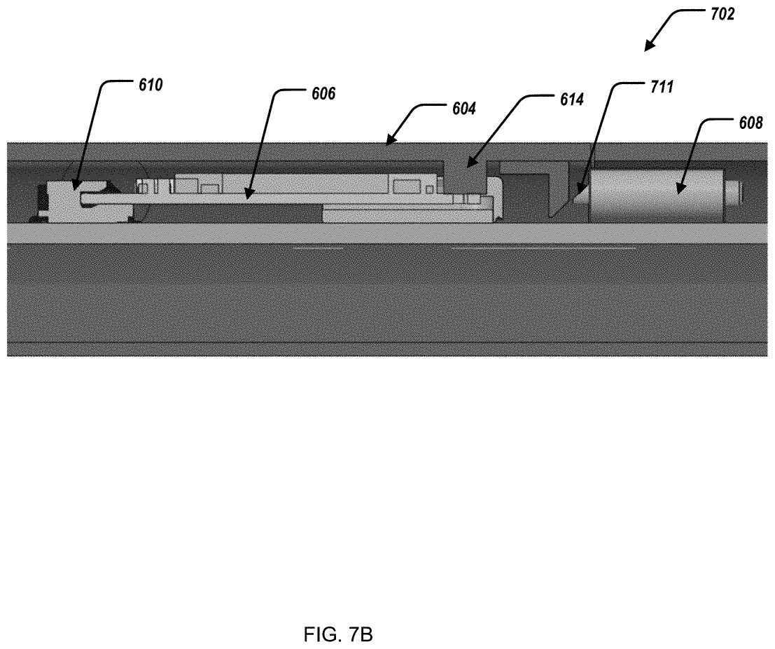

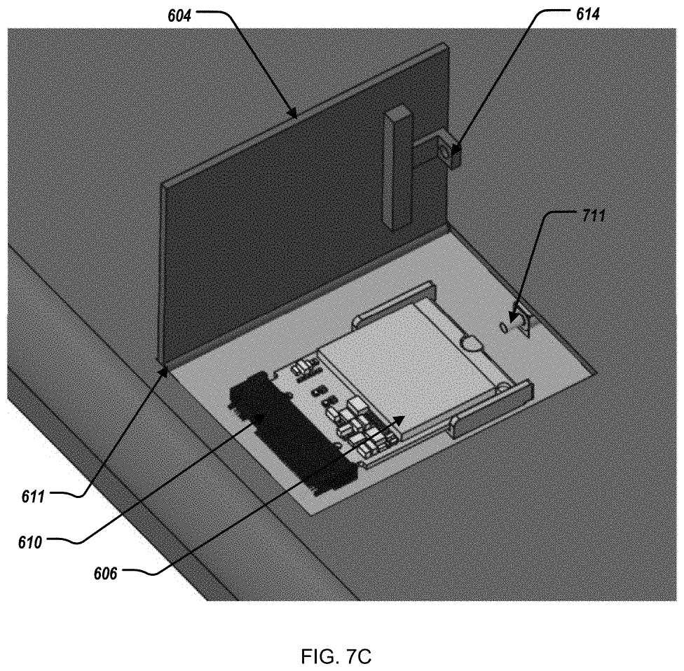

FIG. 7A illustrates a side cut-away view of the information handling system 602, including a secure hardware component retention assembly 702.

The assembly 702 can include the access door 604. The access door 604 can include the coupling member 614. The hardware component 606 can be coupled to the connector 610. The assembly 702 can further include the fastening element 608 coupled to the information handling system 602.

In some examples, the coupling member 614 is an opening. In some examples, the fastening element 608 is a solenoid, and includes a latch pin 711.

The assembly 702 can further include the (torsional) spring hinge 611 coupling the access door 604 to the information handling system, as shown in FIG. 7C.

In some examples, the hardware component 606 is a solid-state drive (SSD). In some examples, the hardware component 606 is a memory module (DIMM). In some examples, the hardware component 606 is a subscriber identification module (SIM).

In some examples, the connector 610 is a M.2 connector.

FIG. 7A illustrates the fastening element 608 in a first state. Specifically, when the fastening element 608 is in the first state, the fastening element 608 is engaged with the coupling member 614 to maintain a first positioning of the access door 604, and further, conceal the hardware component 206 within a casing 311 of the information handling system 702 (shown in FIG. 3A). Specifically, in some examples, the fastening element 608 (solenoid) is in the first state, the latch pin 711 of the solenoid engages with the coupling member 614 (opening) to maintain the first positioning of the access door 604. In some examples, when the fastening element 608 is engaged with the coupling member 614 to maintain the first positioning of the access door 604, the access door 604 is engaged with the casing 311 of the information handling system 602.

The fastening element 608 (solenoid) can receive a signal indicating to transition the fastening element 608 from the first state to a second state, as shown in FIG. 7B. Specifically, the fastening element 608 (solenoid), in response to the signal, disengages from the coupling member 614 (opening) such that the spring hinge 611 rotates the access door 604 so as to expose the hardware component 606, as shown in FIG. 7C. That is, the fastening element 608 (solenoid), in response to the signal, disengages the latch pin 711 from the coupling member 614 (opening) to place the fastening element (608) in the second state.

In short, the fastening element 608 transitions from the first state to the second state in response to the signal.

In some cases, a user of the information handling system 602 provides input that generates the signal to transition the fastening element 608 from the first state to the second state, and provide access to the hardware component 606. The user can be authenticated (e.g., via login credentials or biometric means).

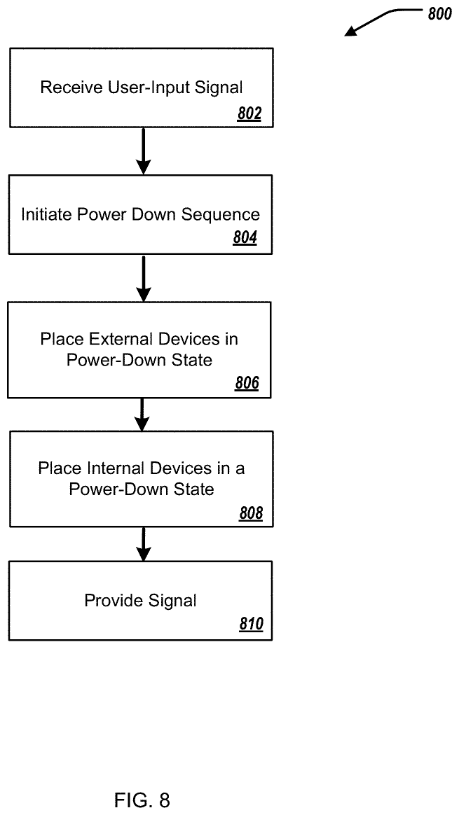

FIG. 8 illustrates a flowchart depicting selected elements of an embodiment of a method 800. The method 800 may be performed by the information handling system 100, the information handling system 202, the EC 220, the fastening element 208, the information handling system 602, the EC 620, and/or the fastening element 608, and with reference to FIGS. 1-7. It is noted that certain operations described in method 800 may be optional or may be rearranged in different embodiments.

A user-input signal is received at the information handling system indicating removal of a hardware component (206, 606) from the information handling system (802). In response to the signal, the EC (220, 620) initiates a power down sequence at the information handling system (804). For example, the EC initiates the shutdown/power down sequence from state S0. The EC (220, 620) can place the external devices (224, 624) in a power-down state (806). For example, the EC can place the hardware component in the power-down state, such as network and radio devices. The EC (220, 620) can place the internal devices (226, 626) in a power-down state (808). For example, the EC can place the CPU and GPU cores in a power-down state. The EC (220, 620) can provide a signal to the secure hardware component retention assembly (402, 702) to transition a fastening element (208, 608) from a first state to a second state to disengage the fastening element (208, 608) from a coupling member (214, 614). As a result, for example, the spring element 212 is able to exert a force to translate the tray assembly 204, and at least a portion of the tray assembly 204 is positioned external to the information handling system 202; and for example, the spring hinge 611 rotates the access door 604 so as to expose the hardware component 606. The EC (220, 620) can power down the remaining components of the information handling system, and the hardware component (206, 606) can be retrieved.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated other-wise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative.

What is claimed is:

1. A secure hardware component retention assembly, comprising:
a tray assembly moveably coupled to an information handling system, the tray assembly including a coupling member and a spring element;
a hardware component coupled to the tray assembly; and
a fastening element coupled to the information handling system;
wherein when the fastening element is in a first state, the fastening element is engaged with the coupling member to maintain a first positioning of the tray assembly internal to the information handling system and the hardware component is engaged with a connector of the information handling system,
wherein when the fastening element is in a second state, the fastening element is disengaged from the coupling member such that the spring element exerts a force to translate the tray assembly so as to i) position at least a portion of the tray assembly external to the information handling system and ii) disengage the hardware component from the connector of the information handling system,
wherein the fastening element transitions from the first state to the second state in response to a signal.

2. The secure hardware component retention assembly of claim 1, further comprising an extension spring coupled to the fastening element, the extension spring exerting a first force on the fastening element to maintain the fastening element in the first state.

3. The secure hardware component retention assembly of claim 2, further comprising a shape memory alloy element coupled to the fastening element, wherein in response to the signal, the shape memory alloy element contracts to exert a second force on the fastening element to overcome the first force of the extension spring and place the fastening element in the second state.

4. The secure hardware component retention assembly of claim 3, wherein the fastening element includes a hooking member and the coupling member includes a post, wherein the extension spring exerts the first force on the fastening element such that the hooking member engages the post to maintain the fastening element in the first state.

5. The secure hardware component retention assembly of claim 4, wherein the shape memory alloy element contracts, in response to the signal, to exert the second force on the fastening element such that the hooking member disengages from the post to place the fastening element in the second state.

6. The secure hardware component retention assembly of claim 1, wherein when the fastening element is in the first state, the spring element is in a compressed state.

7. The secure hardware component retention assembly of claim 1, wherein the fastening element is rotatably coupled to the information handling system.

8. The secure hardware component retention assembly of claim 1, wherein the fastening element is a solenoid and the coupling member is an opening, wherein when the solenoid is in the first state, a latch pin of the solenoid engages with the opening to maintain the first positioning of the tray assembly.

9. The secure hardware component retention assembly of claim 8, further comprising a shape memory alloy element coupled to the solenoid, wherein the shape memory alloy element contracts, in response to the signal, to disengage the latch pin of the solenoid from the opening to place the solenoid in the second state.

10. The secure hardware component retention assembly of claim 1, wherein the hardware component is a solid-state drive.

11. The secure hardware component retention assembly of claim 1, wherein the hardware component is a memory module.

12. The secure hardware component retention assembly of claim 1, wherein the hardware component is a subscriber identification module.

13. The secure hardware component retention assembly of claim 1, wherein the connector is a M.2 connector.

14. A secure hardware component retention assembly, comprising:
an access door including a coupling member;
a torsional spring hinge coupling the access door to an information handling system;
a hardware component engaged with a connector of the information handling system; and
a fastening element coupled to the information handling system,
wherein when the fastening element is in a first state, the fastening element is engaged with the coupling member to maintain a first positioning of the access door so as to conceal the hardware component within a casing of the information handling system,
wherein when the fastening element is in a second state, the fastening element is disengaged from the coupling member such that the torsional spring hinge rotates the access door so as to expose the hardware component,
wherein the fastening element transitions from the first state to the second state in response to a signal.

15. The secure hardware component retention assembly of claim 14, wherein the fastening element is a solenoid and the coupling member includes an opening, wherein when the solenoid is in the first state, a latch pin of the solenoid engages with the opening to maintain the first positioning of the access door.

16. The secure hardware component retention assembly of claim 15, wherein in response to the signal, the solenoid disengages the latch pin from the opening to place the solenoid in the second state.

17. The secure hardware component retention assembly of claim 14, wherein the fastening element is engaged with the coupling member to maintain the first positioning of the access door such that the access door is engaged with the casing of the information handling system.

18. The secure hardware component retention assembly of claim 14, wherein the hardware component is a solid-state drive.

19. The secure hardware component retention assembly of claim 14, wherein the hardware component is a memory module.

20. A method, comprising:
receiving a user-input signal indicating a removal of a hardware component from an information handling system;
in response to the signal, initiating a power down sequence at the information handling system, including:
placing devices external to a system on a chip (SoC) of the information handling system in a power-down state;
placing devices internal to the SoC in a power-down state; and
providing a signal to a secure hardware component retention assembly to transition a fastening element of the secure hardware component retention assembly from a first state to a second state to disengage the fastening element from a coupling member.

What is claimed is:

1. A secure hardware component retention assembly, comprising:
a tray assembly moveably coupled to an information handling system, the tray assembly including a coupling member and a spring element;
a hardware component coupled to the tray assembly; and
a fastening element coupled to the information handling system;
wherein when the fastening element is in a first state, the fastening element is engaged with the coupling member to maintain a first positioning of the tray assembly internal to the information handling system and the hardware component is engaged with a connector of the information handling system,
wherein when the fastening element is in a second state, the fastening element is disengaged from the coupling member such that the spring element exerts a force to translate the tray assembly so as to i) position at least a portion of the tray assembly external to the information handling system and ii) disengage the hardware component from the connector of the information handling system,
wherein the fastening element transitions from the first state to the second state in response to a signal.

2. The secure hardware component retention assembly of claim 1, further comprising an extension spring coupled to the fastening element, the extension spring exerting a first force on the fastening element to maintain the fastening element in the first state.

3. The secure hardware component retention assembly of claim 2, further comprising a shape memory alloy element coupled to the fastening element, wherein in response to the signal, the shape memory alloy element contracts to exert a second force on the fastening element to overcome the first force of the extension spring and place the fastening element in the second state.

4. The secure hardware component retention assembly of claim 3, wherein the fastening element includes a hooking member and the coupling member includes a post, wherein the extension spring exerts the first force on the fastening element such that the hooking member engages the post to maintain the fastening element in the first state.

5. The secure hardware component retention assembly of claim 4, wherein the shape memory alloy element contracts, in response to the signal, to exert the second force on the fastening element such that the hooking member disengages from the post to place the fastening element in the second state.

6. The secure hardware component retention assembly of claim 1, wherein when the fastening element is in the first state, the spring element is in a compressed state.

7. The secure hardware component retention assembly of claim 1, wherein the fastening element is rotatably coupled to the information handling system.

8. The secure hardware component retention assembly of claim 1, wherein the fastening element is a solenoid and the coupling member is an opening, wherein when the solenoid is in the first state, a latch pin of the solenoid engages with the opening to maintain the first positioning of the tray assembly.

9. The secure hardware component retention assembly of claim 8, further comprising a shape memory alloy element coupled to the solenoid, wherein the shape memory alloy element contracts, in response to the signal, to disengage the latch pin of the solenoid from the opening to place the solenoid in the second state.

10. The secure hardware component retention assembly of claim 1, wherein the hardware component is a solid-state drive.

11. The secure hardware component retention assembly of claim 1, wherein the hardware component is a memory module.

12. The secure hardware component retention assembly of claim 1, wherein the hardware component is a subscriber identification module.

13. The secure hardware component retention assembly of claim 1, wherein the connector is a M.2 connector.

14. A secure hardware component retention assembly, comprising:
an access door including a coupling member;
a torsional spring hinge coupling the access door to an information handling system;
a hardware component engaged with a connector of the information handling system; and
a fastening element coupled to the information handling system,
wherein when the fastening element is in a first state, the fastening element is engaged with the coupling member to maintain a first positioning of the access door so as to conceal the hardware component within a casing of the information handling system,
wherein when the fastening element is in a second state, the fastening element is disengaged from the coupling member such that the torsional spring hinge rotates the access door so as to expose the hardware component,
wherein the fastening element transitions from the first state to the second state in response to a signal.

15. The secure hardware component retention assembly of claim 14, wherein the fastening element is a solenoid and the coupling member includes an opening, wherein when the solenoid is in the first state, a latch pin of the solenoid engages with the opening to maintain the first positioning of the access door.

16. The secure hardware component retention assembly of claim 15, wherein in response to the signal, the solenoid disengages the latch pin from the opening to place the solenoid in the second state.

17. The secure hardware component retention assembly of claim 14, wherein the fastening element is engaged with the coupling member to maintain the first positioning of the access door such that the access door is engaged with the casing of the information handling system.

18. The secure hardware component retention assembly of claim 14, wherein the hardware component is a solid-state drive.

19. The secure hardware component retention assembly of claim 14, wherein the hardware component is a memory module.

20. A method, comprising:
receiving a user-input signal indicating a removal of a hardware component from an information handling system;
in response to the signal, initiating a power down sequence at the information handling system, including:
placing devices external to a system on a chip (SoC) of the information handling system in a power-down state;
placing devices internal to the SoC in a power-down state; and
providing a signal to a secure hardware component retention assembly to transition a fastening element of the secure hardware component retention assembly from a first state to a second state to disengage the fastening element from a coupling member.
